(19) United States
(12) Patent Application Publication
(10) Pub. No.: US 2017/0336480 A1
(43) Pub. Date: Nov. 23, 2017

(54) Method for Measuring Magnetic Field Gradients

(71) Applicants: Francesco Narducci, Dowell, MD (US); Sara DeSavage, Lexington Park, MD (US)

(72) Inventors: Francesco Narducci, Dowell, MD (US); Sara DeSavage, Lexington Park, MD (US)

(73) Assignee: United States of America as represented by the Secretary of the Navy, Patuxent River, MD (US)

(21) Appl. No.: 15/158,083

(22) Filed: May 18, 2016

(51) Int. Cl. G01R 33/032; G01R 33/022

(52) U.S. Cl. CPC G01R 33/032; G01R 33/022

(57) ABSTRACT

A method for measuring magnetic field gradients that includes laser cooling atoms in a dark spot magneto-optical trap with an illuminated part, releasing the atoms, laser cooling the sample of atoms a second time, dividing the sample of atoms in half such that the first half of atoms are in the illuminated part of the trap, tossing the first half of atoms, leaving the second half of atoms behind, obtaining a RamanRaman spectrum from the first half of atoms and the second half of atoms and obtaining magnetic field measurements of the first half of atoms and the second half of atoms, and calculating a magnetic field gradient by subtracting the magnetic field measurements of the first half of atoms from the second half of atoms, then dividing the difference by the separation of the first half of atoms and the second half of atoms.

### STATEMENT OF GOVERNMENT INTEREST

The invention described herein may be manufactured and used by or for the Government of the United States of America for governmental purposes without payment of any royalties thereon or therefor.

### BACKGROUND

Laser-cooled atoms are atoms that have been cooled by appropriately tuned laser fields to temperatures below 1 mK. Because atoms that are this cold are also slow moving, they can often be used to make high-precision measurements of forces, such as those due to acceleration or rotation or magnetic fields/magnetic field gradients.

### SUMMARY

The present invention is directed to a system with the needs enumerated above and below.

The present invention is directed to a method for measuring magnetic field gradients that includes laser cooling a sample of atoms that are contained in a dark spot magneto-optical trap with an illuminated part, releasing the atoms from the dark spot magneto-optical trap after laser cooling the sample of atoms, laser cooling the sample of atoms a second time, dividing the sample of atoms into a first half of atoms and a second half of atoms, such that the first half of atoms are in the illuminated part of the dark spot magneto-optical trap, tossing the first half of atoms, leaving the second half of atoms behind, obtaining a Raman spectrum from the first half of atoms and the second half of atoms and obtaining magnetic field measurements of the first half of atoms and the second half of atoms, and calculating a magnetic field gradient by finding a difference by subtracting the magnetic field measurements of the first half of atoms from the second half of atoms, then dividing the difference by the separation of the first half of atoms and the second half of atoms.

It is a feature of the present invention to provide a method for measuring magnetic field gradients that simultaneously measures the Raman spectrum on the two samples of atoms, thereby simultaneously measuring the magnetic field at the location of the atoms.

It is a feature of the present invention to provide a method for measuring magnetic field gradients that is able to toss half of the atoms in the trap while leaving the other half behind.

It is a feature of the present invention to provide a methodology to extract a measurement of the magnetic field gradient by measuring the magnetic field in two locations simultaneously and dividing by the distance between the two locations.

It is a feature of the present invention that envisioned uses that include, but are not limited to, navigation, magnetic field mapping, submarine and mine detection and oil exploration.

### DESCRIPTION

The preferred embodiments of the present invention are illustrated by way of example below. The method for measuring magnetic field gradients includes laser cooling a sample of atoms that are contained in a dark spot magneto-optical trap with an illuminated part, releasing the atoms from the dark spot magneto-optical trap after laser cooling the sample of atoms, laser cooling the sample of atoms a second time, dividing the sample of atoms into a first half of atoms and a second half of atoms, such that the first half of atoms are in the illuminated part of the dark spot magneto-optical trap, tossing the first half of atoms, leaving the second half of atoms behind, obtaining a Raman spectrum from the first half of atoms and the second half of atoms and obtaining magnetic field measurements of the first half of atoms and the second half of atoms, and calculating a magnetic field gradient by finding a difference by subtracting the magnetic field measurements of the first half of atoms from the second half of atoms, then dividing the difference by the separation of the first half of atoms and the second half of atoms.

In the description of the present invention, the invention will be discussed in a laboratory environment; however, this invention can be utilized for any type of application that requires the measurement of magnetic fields.

Atoms are laser cooled to temperatures below 1 milliKelvin. Laser cooling of atoms involves, but without limitation, shining laser light at atoms from six directions with an appropriate frequency of light and an appropriate tailored magnetic field. The combination of laser light and a magnetic field creates a trap for the atoms. The laser light includes a cooling frequency and a repumper frequency. The frequency of the cooling laser is tuned slightly less than the frequency of the cycling transition of the atom. The frequency of the repumper is tuned to depopulate the unwanted ground state. The invention uses rubidium atoms, but any atom amendable to laser cooling, e.g. sodium, lithium, potassium, cesium, etc., can be utilized. The cooling of atoms needs to be done in an ultra-high vacuum system (better than 10⁻⁸ torr).

The invention uses a dark spot trap. A dark spot trap, but without limitation, may include laser beams comprised of a cooling laser and a repumper laser with appropriate optics to create a shadow of the repumper laser in the middle of the laser beams. The use of the dark spot trap allows for the tossing half the atoms while leaving the other half behind.

The atoms are released from the dark spot magneto-optical trap, which can be done by turning off the magnetic field. The atoms are further cooled a second time, which can be done by changing the laser cooling frequency. The sample of atoms is then divided into a first half of atoms and a second half of atoms, such that the first half of atoms are in the illuminated part of the dark spot magneto-optical trap.

The atoms are then tossed in the vacuum system. In the preferred embodiment, the toss is done by changing the frequency of one of the cooling beams by a small amount and the frequency of the other cooling beam by the same amount in the other direction, creating a force on the atoms. Because the atoms were trapped in a dark spot trap, the atoms in the center of the trap do not feel the force and hence remain behind. The atoms away from the center of the trap, do feel the force and hence are launched in the direction of the force.

To obtain a RamanRaman spectrum, Raman spectroscopy may be performed on both samples of atoms. This can include applying a pulse of light from a Raman laser in the direction connecting both samples so as to illuminate both samples of atoms. A Raman laser typically includes two laser frequencies, each of which is tuned far off resonance, but whose frequency difference coincides with the frequency difference in the ground states of the atom. To perform the spectroscopy, we may first optically pump both samples of atoms into the lower ground state by turning off the repumper light and leaving the cooling beams on for a short period of time. Then the cooling beams are turned off. Then the Raman beam is applied, causing atoms to transition to the upper ground state. The number of atoms that transition to the upper state are then measured by turning the cooling beams back on. The cooling beams cause the atoms to fluoresce. In the preferred embodiment, the fluorescence is collected by two detectors, each one looking at one sample of atoms. The spectroscopy results in spectral lines, the spacing of which depends on the magnetic field experienced by the atoms. Therefore, we can extract the magnetic field at the location of both samples of atoms, resulting in a simultaneous measurement of the magnetic field at both locations. By knowing the separation of the two samples of atoms, we can then calculate the magnetic field gradient by taking the difference in the two magnetic fields divided by the distance between the samples of atoms.

When introducing elements of the present invention or the preferred embodiment(s) thereof, the articles “a,” “an,” “the,” and “said” are intended to mean there are one or more of the elements. The terms “comprising,” “including,” and “having” are intended to be inclusive and mean that there may be additional elements other than the listed elements.

Although the present invention has been described in considerable detail with reference to certain preferred embodiments thereof, other embodiments are possible. Therefore, the spirit and scope of the appended claims should not be limited to the description of the preferred embodiment(s) contained herein.

What is claimed is:

1. A method of for measuring magnetic field gradients, the method comprising:
laser cooling a sample of atoms that are contained in a dark spot magneto-optical trap, the dark spot magneto-optical trap having an illuminated part;
releasing the atoms from the dark spot magneto-optical trap after laser cooling the sample of atoms;
laser cooling the sample of atoms a second time;
dividing the sample of atoms into a first half of atoms and a second half of atoms, such that the first half of atoms are in the illuminated part of the dark spot magneto-optical trap;
tossing the first half of atoms;
leaving the second half of atoms behind;
obtaining a RamanRaman spectrum from the first half of atoms and the second half of atoms and obtaining magnetic field measurements of the first half of atoms and the second half of atoms;
calculating a magnetic field gradient by finding a difference by subtracting the magnetic field measurements of the first half of atoms from the second half of atoms, then dividing the difference by the separation of the first half of atoms and the second half of atoms.
